(19) United States
(12) Patent Application Publication
(10) Pub. No.: US 2009/0295369 A1
(43) Pub. Date: Dec. 3, 2009

(54) Current sensing circuit

(76) Inventor: Doris YANG, Zhubei City (TW)

Correspondence Address: SINORICA, LLC, 2275 Research Blvd., Suite 500, ROCKVILLE, MD, 20850, US

(21) Appl. No.: 12/131,213

(22) Filed: Jun. 2, 2008

(51) Int. Cl. G01R 1/30

(52) U.S. Cl. 324/123 R

(57) ABSTRACT

A current sensing circuit is coupled to a current amplifier. The current sensing circuit comprises a power MOS, a switch and a switching resistor. The switching resistor has a value of ranging from approximately some kiliohms to approximately several ten kiliohms. The power MOS outputs a large current. The switch determines a sensing period. The power MOS provides a low on-resistance characteristic such that a sensing resistor is capable of being eliminated. The switching resistor senses a voltage drop while the switch is turned on. The sensed voltage is amplified by the current amplifier. The switching resistor has a relatively low accuracy resistance.

### BACKGROUND OF THE INVENTION

1. Field of the Invention

The present invention relates generally to a current sensing technique, and more particularly to a current sensing circuit that is easily to be fabricated in an integrated circuit.

2. Description of Prior Art

One approach to sensing the current of a power MOS is to fabricate a sensing resistor Rs in series with a sensing MOS. Referring to FIG. 1, a conventional current sensing circuit having two MOS FETs in parallel is shown. The MOS 12 is called the power MOS. the MOS 14 is called the sensing MOS. The FETS 12, 14 have the same characteristics since they are fabricated on a common substrate by the same manufacturing process. The load current is mirrored at a lower level through the sensing MOS 14. The current I2 in the sensing MOS 14 is much smaller than the current I1 in the power MOS 12. However, since the two FETS 12, 14 have substantially the same characteristics, the devices are proportional to one another. The current I1 in the power MOS 12 can be determined if the sensing MOS 14 current I2 is known, since the two currents I1, I2 are related to one another. The current quantity can be converted to voltage by the sensing resistor Rs.

The circuit uses the voltage drop across the sensing resistor Rs to sense the current of the power MOS 12. However, when the sensing resistor Rs is fabricated in integrated circuit form, it is difficult to accurately control the low resistance value ranging from ten ohms to hundreds ohms, without using excessive integrated circuit area.

### SUMMARY OF THE INVENTION

The present invention provides a current sensing technique to resolve the foregoing problems faced by the conventional current sensing circuit. The present invention also has the advantage to avoid complexity in fabricating a sensing resistor in an integrated circuit.

In accordance with an aspect of the present invention, a current sensing circuit is coupled to a current amplifier. The current sensing circuit comprises a power MOS, a switch and a switching resistor. The switching resistor has a value of ranging from approximately some kiliohms to approximately several ten kiliohms. The power MOS outputs a large current. The switch determines a sensing period. The power MOS provides a low on-resistance characteristic such that a sensing resistor is capable of being eliminated. the switching resistor senses a voltage drop while the switch is turned on.

In the preferred embodiment of the invention, the sensed voltage is amplified by the current amplifier. The switching resistor has a relatively low accuracy resistance.

The present invention may best be understood through the following description with reference to the accompanying drawings, in which:

### BRIEF DESCRIPTION OF THE DRAWINGS

FIG. 1 shows a schematic diagram of a conventional current sensing circuit with a sensing resistor.

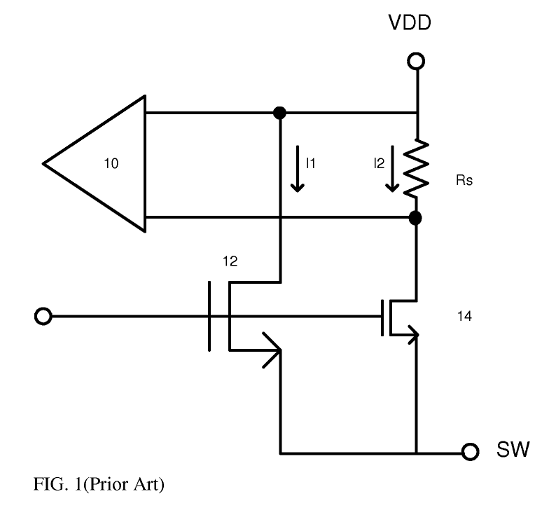

FIG. 2 shows a schematic diagram of a current sensing circuit of the preferred embodiment according to the present invention.

### DETAILED DESCRIPTION OF THE PREFERRED EMBODIMENT

The present invention will now be described more specifically with reference to the following embodiments. It is to be noted that the following descriptions of preferred embodiments of this invention are presented herein for the purpose of illustration and description only. It is not intended to be exhaustive or to be limited to the precise form disclosed.

The present invention describes a new current sensing circuit that will eliminate an accurate sensing resistor. Accordingly, the problem faced by the prior arts can be solved completely. The presently described current sensing circuit, thus, serves demands much more adequately.

According to the preferred embodiment of the present invention, a current sensing circuit is coupled to a current amplifier. The current sensing circuit comprises a power MOS, a switch and a switching resistor. The switching resistor has a value of ranging from approximately some kiliohms to approximately several ten kiliohms. The power MOS outputs a large current. The switch determines a sensing period. The power MOS provides a low on-resistance characteristic such that a sensing resistor is capable of being eliminated. the switching resistor senses a voltage drop while the switch is turned on.

The sensed voltage is amplified by the current amplifier. The switching resistor has a relatively low accuracy resistance.

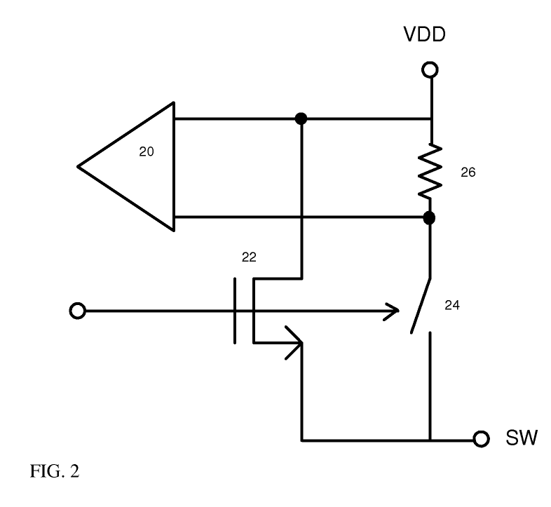

Referring to FIG. 2, a schematic diagram of a current sensing circuit of the preferred embodiment according to the present invention is shown. The current sensing circuit comprises a power MOS 22, a switch 24 and a switching resistor 26.

The power MOS 22 has a very low Rds-on (turn-on impedance from drain to source) of the power MOS 22. The ON-resistance of the power MOS 22 can be utilized as a sensing resistor. Thus an accurate sensing resistor can be eliminated.

The power MOS 22 may output a large current. The switching resistor 26 may be a large resistor having a value of ranging from approximately some kiliohms to approximately several ten kiliohms. The switch 24 is used for determining the sensing period. At the time the switch 24 is turned on such that the switching resistor 26 senses the voltage drop between the VDD end and SW end. The sensed voltage is amplified by the amplifier 20.

A resistor with a relatively low accuracy resistance can be applied to the switching resistor 26, thus it is easier to fabricate the circuit of FIG. 2 in integrated circuit form.

The present invention relates to a current sensing circuit which is easily fabricated. Hence, the shortcoming of the difficulty of accurately controlling the low resistance can be entirely avoided.

While the invention has been described in terms of what are presently considered to be the most practical and preferred embodiments, it is to be understood that the invention need not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A current sensing circuit coupled to a current amplifier, said current sensing circuit comprising: a power MOS for outputting a large current; a switch for determining a sensing period; and a switching resistor having a value of ranging from approximately some kiliohms to approximately several ten kiliohms, wherein said power MOS provides a low on-resistance characteristic; such that a sensing resistor is capable of being eliminated, and said switching resistor senses a voltage drop while said switch is turned on.

2. The current sensing circuit according to claim 1, wherein said sensed voltage is amplified by said current amplifier

3. The current sensing circuit according to claim 1, wherein said switching resistor has a relatively low accuracy resistance.
